(19) United States
(12) Patent Application Publication
(10) Pub. No.: US 2026/0371489 A1
(43) Pub. Date: Nov. 19, 2026

(54) WIRING BOARD AND MOUNTING STRUCTURE USING THE SAME

(71) Applicant: KYOCERA CORPORATION, Kyoto-shi, Kyoto (JP)

(72) Inventor: Hidetoshi YUGAWA, Kyoto-shi (JP)

(73) Assignee: KYOCERA CORPORATION, Kyoto-shi, Kyoto (JP)

(21) Appl. No.: 19/124,343

(22) PCT Filed: Oct. 20, 2023
(86) PCT No.: PCT/JP2023/037966

§ 371 Date: Apr. 25, 2025

(30) Foreign Application Priority Data
Oct. 28, 2022 (JP) 2022-173508

(51) Int. Cl. H05K 1/11; H05K 1/09; H05K 1/181

(52) U.S. Cl. CPC H05K 1/116; H05K 1/09; H05K 1/181

(57) ABSTRACT

A wiring board according to the present disclosure includes: a first insulation layer having a first surface; a land conductor located on the first surface; a second insulation layer covering the first surface and the land conductor, and has a second surface on a side opposite to the first insulation layer; a via hole penetrating from the second surface of the second insulation layer to the land conductor; and a via-hole electrical conductor located in the via hole and is in contact with the land conductor. The via-hole electrical conductor includes a first region in a surface of the via-hole electrical conductor, the first region being in contact with the land conductor. The first region partially includes an oxidized nichrome layer.

### TECHNICAL FIELD

The present invention relates to a wiring board and a mounting structure using the same.

### BACKGROUND OF INVENTION

In a wiring board, a via hole formed in an insulation layer is filled with a plating film (via-hole electrical conductor) in order to electrically connect electrical conductor layers located on upper and lower surfaces of the insulation layer, as disclosed in Patent Document 1. The via-hole electrical conductor is usually connected to a via land at a via bottom.

### CITATION LIST

### Patent Literature

Patent Document 1: JP 2001-127155 A

### SUMMARY

### Solution to Problem

A wiring board according to the present disclosure includes: a first insulation layer having a first surface; a land conductor located on the first surface; a second insulation layer covering the first surface and the land conductor, and has a second surface on a side opposite to the first insulation layer; a via hole penetrating from the second surface of the second insulation layer to the land conductor; and a via-hole electrical conductor located in the via hole and is in contact with the land conductor. The via-hole electrical conductor includes a first region in a surface of the via-hole electrical conductor, the first region being in contact with the land conductor. The first region partially includes an oxidized nichrome layer.

In addition, a mounting structure according to the present disclosure includes the wiring board described above, and an electronic component located on at least one of an upper surface or a lower surface of the wiring board.

### BRIEF DESCRIPTION OF THE DRAWINGS

FIG. 1 is an explanatory diagram for describing a wiring board according to one embodiment of the present disclosure.

FIG. 2 is an enlarged cross-sectional view for describing region X illustrated in FIG. 1.

FIG. 3 illustrates explanatory diagrams for describing an example of a method of forming a via-hole electrical conductor in the wiring board according to one embodiment of the present disclosure.

FIG. 4 illustrates explanatory diagrams for describing the example of the method of forming a via-hole electrical conductor in the wiring board according to one embodiment of the present disclosure.

FIG. 5 illustrates explanatory diagrams for describing the example of the method of forming a via-hole electrical conductor in the wiring board according to one embodiment of the present disclosure.

FIG. 6 are cross-sectional photographs illustrating a state after a via-hole electrical conductor pull test in the wiring board according to one embodiment of the present disclosure.

### DESCRIPTION OF EMBODIMENTS

As described above, a via-hole electrical conductor is usually connected to a via land at a via bottom. In the via-hole electrical conductor, stress is likely to be concentrated on a connection portion between the via bottom and the via land due to a difference in thermal expansion coefficient and a difference in Young's modulus between the via-hole electrical conductor such as copper and a resin forming an insulation layer. Therefore, the connection portion between the via bottom and the via land is prone to breakage, resulting in poor connection reliability of the via-hole electrical conductor. Therefore, there is a demand for a wiring board having excellent connection reliability of a via-hole electrical conductor without deterioration of electrical properties thereof.

A wiring board according to the present disclosure has a configuration as described in SOLUTION TO PROBLEM, thereby reducing deterioration of electrical properties thereof and providing excellent connection reliability of a via-hole electrical conductor.

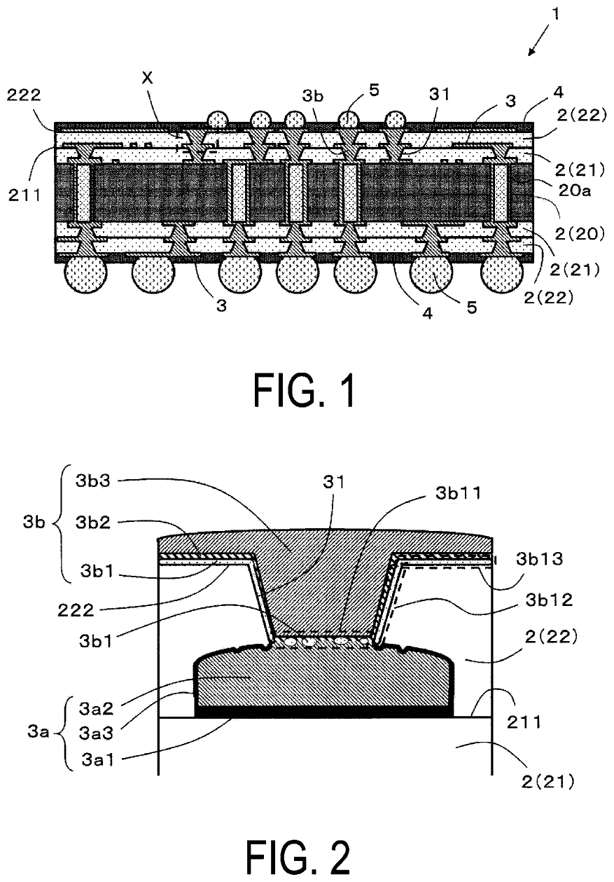

A wiring board according to one embodiment of the present disclosure will be described with reference to FIGS. 1 and 2. FIG. 1 is an explanatory diagram for describing a wiring board 1 according to one embodiment of the present disclosure. As illustrated in FIG. 1, the wiring board 1 according to one embodiment includes insulation layers 2, electrical conductor layers 3, and solder resists 4.

The insulation layer 2 includes a core insulation layer 20, a first insulation layer 21, and a second insulation layer 22. The core insulation layer 20 is not particularly limited as long as the core insulation layer 20 is made of a material having insulation. Examples of a material with insulation include resins such as epoxy resin, bismaleimide-triazine resin, polyimide resin, and polyphenylene ether resin. Two or more types of the resin may be mixed and used.

A thickness of the core insulation layer 20 is not particularly limited and is, for example, 40 μm or more and 20 mm or less. The core insulation layer 20 is not necessarily required. For example, in a substrate called a coreless substrate or a 2.3D substrate, the core insulation layer is not used. For example, the thickness of the core insulation layer 20 may exceed 10 mm similar to a motherboard.

The core insulation layer 20 may contain a reinforcing material. Examples of the reinforcing material include insulation fabrics such as glass fiber, glass nonwovens, aramid nonwoven, aramid fiber, and polyester fiber. Two or more types of reinforcing materials may be used in combination. Furthermore, an inorganic insulation filler such as silica, barium sulfate, talc, clay, glass, calcium carbonate, and titanium oxide may be dispersed in the core insulation layer 20. Two or more types of inorganic insulating fillers may be used in combination. In general, an inorganic insulating filler such as silica or alumina, which is not chemically corroded by acid or alkali, is often used in a substrate intended for fine wiring. This reduces insulation degradation such as ion migration even when the substrate is in high temperature and high humidity and is applied.

A through-hole conductor 20a is located in the core insulation layer 20 to electrically connect upper and lower surfaces of the core insulation layer 20. The through-hole conductor 20a is located in a through-hole penetrating from the upper surface to the lower surface of the core insulation layer 20. The through-hole conductor 20a is formed by, for example, metallic plating such as copper plating. The through-hole conductor 20a is connected to the electrical conductor layers 3 formed on both surfaces of the core insulation layer 20. The through-hole conductor 20a may be located only on an inner wall surface of the through-hole or the through-hole may be filled with the through-hole conductor 20a.

The electrical conductor layer 3 is not limited as long as the electrical conductor layer 3 is an electrical conductor such as a metal. Specifically, the electrical conductor layer 3 is made of a metal foil such as a copper foil, a metal plating such as a copper plating, or the like. A thickness of the electrical conductor layer 3 is not particularly limited and is, for example, 2 μm or more and 50 μm or less. The thickness of the electrical conductor layer 3 tends to decrease with miniaturization of the wiring.

A build-up layer is located on both surfaces of the core insulation layer 20. The build-up layer has a structure in which the electrical conductor layer 3 and the insulation layer 2 are alternately laminated. In the wiring board 1 according to one embodiment, when focusing on any two insulation layers 2 in contact with each other among the insulation layers 2 constituting the build-up layer, the insulation layer 2 on a side close to the core insulation layer 20 corresponds to the first insulation layer 21, and the insulation layer 2 on the other side corresponds to the second insulation layer 22.

Specifically, when the build-up layer includes three insulation layers, focusing on the insulation layer (first insulation layer) located on the surface of the core insulation layer and the insulation layer (second insulation layer) located on the surface of the first insulation layer, the first insulation layer on a side close to the core insulation layer corresponds to the first insulation layer, and the second insulation layer corresponds to the second insulation layer. When focusing on the second insulation layer and the insulation layer (third insulation layer) located on the surface of the second insulation layer, the second insulation layer on a side close to the core insulation layer corresponds to the first insulation layer, and the third insulation layer corresponds to the second insulation layer.

The insulation layers 2 (the first insulation layer 21 and the second insulation layer 22) constituting the build-up layer are not particularly limited as long as the insulation layers 2 are made of a material having insulation, similar to the core insulation layer 20. Examples of the material include resins such as an epoxy resin, a bismaleimide-triazine resin, a polyimide resin, and a polyphenylene ether resin. Two or more types of the resin may be mixed and used. The insulation layers 2 constituting the build-up layer may be made of the same resin or different resins. The insulation layers 2 constituting the build-up layer and the core insulation layer 20 may be made of the same resin or different resins. A thickness of the insulation layer 2 constituting the build-up layer is not particularly limited and is, for example, 5 μm or more and 100 μm or less. The insulation layers 2 constituting the build-up layer may have the same thickness or different thicknesses.

The insulation layers 2 constituting the build-up layer may also contain a reinforcing material. Examples of the reinforcing material include insulation fabrics such as glass fiber, glass nonwovens, aramid nonwoven, aramid fiber, and polyester fiber. Two or more types of reinforcing materials may be used in combination. In addition, an inorganic insulation filler such as silica, alumina, aluminum oxide, barium sulfate, talc, clay, glass, calcium carbonate, or titanium oxide may be dispersed also in the insulation layers 2 constituting the build-up layer. Two or more types of inorganic insulating fillers may be used in combination.

As illustrated in FIG. 1, the solder resist 4 may be located on the surface of the build-up layer. The solder resist 4 is formed of a resin, such as an acrylic modified epoxy resin. The solder resist 4 is provided with an opening for electrically connecting the electrical conductor layer 3 and an electrode of an element via the solder 5. Examples of the element include a semiconductor integrated circuit element and an opto-electronic element.

A via-hole electrical conductor 3b is formed in the insulation layers 2 constituting the build-up layer in order to electrically connect the upper and lower surfaces of the insulation layers 2 constituting the build-up layer. The via-hole electrical conductor 3b is located in a via hole 31 formed to penetrate the insulation layers 2 constituting the build-up layer. That is, as illustrated in FIG. 2, the via-hole electrical conductor 3b is located in the via hole 31 penetrating from a second surface 222 of the second insulation layer 22 to the land conductor 3a. FIG. 2 is an enlarged cross-sectional view for describing region X illustrated in FIG. 1. The second insulation layer 22 covers a first surface 211 of the first insulation layer 21 and the land conductor 3a located on the first surface 211. The second surface 222 of the second insulation layer 22 is a surface on a side opposite to the first insulation layer 21.

As illustrated in FIG. 2, the via hole 31 formed in the second insulation layer 22 is filled with the via-hole electrical conductor 3b, and a bottom portion (a bottom surface on a side close to the first surface 211) thereof is in contact with the land conductor 3a. The land conductor 3a and the via-hole electrical conductor 3b are portions of the electrical conductor layer 3.

The land conductor 3a is located on the first surface 211 of the first insulation layer 21 and includes a seed layer 3a1, a plating layer 3a2, and a surface treatment layer 3a3. The seed layer 3 a1 may contain, for example, nichrome, and have a thickness of 1 nm or more and 100 nm or less. The plating layer 3 a2 is located on a surface of the seed layer 3 a1. The plating layer 3a2 includes, for example, Cu. The surface treatment layer 3a3 is positioned to cover the plating layer 3a2. The surface treatment layer 3a3 includes a metal or alloy such as tin, titanium, chromium, and nichrome.

As illustrated in FIG. 2, the via-hole electrical conductor 3b includes an oxidized nichrome layer 3b1, a nichrome layer 3b2, and a plating layer 3b3. The oxidized nichrome layer 3b1 is formed by oxidizing a part of the nichrome layer 3b2. A thickness of the oxidized nichrome layer 3 b1 may be 1 nm or more and 100 nm or less. The oxidized nichrome layer 3b1 has such a thickness, so that the wiring board 1 having excellent connection reliability of the via-hole electrical conductor 3b can be provided without deterioration of electrical properties thereof.

The oxidized nichrome layer 3b1 illustrated in FIG. 2 is located from a surface of the second surface 222 of the second insulation layer 22 to an inner wall surface of the via hole 31. On the second surface 222 of the second insulation layer 22, a region where the oxidized nichrome layer 3b1 is located is defined as a third region 3b13. On the inner wall surface of the via hole 31, a region where the oxidized nichrome layer 3b1 is located is defined as a second region 3b12.

In the wiring board 1 according to one embodiment, the oxidized nichrome layer 3b1 is partially located in a region (a first region 3b11) where the land conductor 3b and the via-hole electrical conductor 3b11 are in contact with each other. Since the oxidized nichrome layer 3b1 is partially located in the first region 3b11, stress applied to the via bottom (the first region 3b11) is relieved. That is, the oxidation of nickel having a high Young's modulus decreases the Young's modulus and relieves the stress applied to the first region 3b11. Further, since the oxidized nichrome layer 3b1 is partially located in the first region 3b11, the stress relieving effect is exhibited without deterioration of electric resistance.

The oxidized nichrome layer 3b1 is not limited as long as the oxidized nichrome layer 3b1 is partially located in the first region 3b11. In other words, it can be said that the oxidized nichrome layer 3b1 is scattered in the first region 3b11 in a plan view. The oxidized nichrome layer 3b1 may be unevenly distributed in the first region 3b11 in a plan view. In the case where the oxidized nichrome layer is scattered, the imbalance in stress relief in the first region 3b11 is reduced. For example, when the first region 3b11 is seen in a plan view, an area occupied by the oxidized nichrome layer 3b1 may be 30% or more and 70% or less. The oxidized nichrome layer 3b1 is located in such an area, so that the stress relieving effect is sufficiently exhibited while electric resistance is sufficiently maintained. An area ratio occupied by the oxidized nichrome layer 3b1 in the first region 3b11 may be calculated by, for example, performing surface analysis without oxidizing the first region 3b11. Specifically, the first region 3b11 of the wiring board 1 may be exposed by a focused ion beam (FIB) or the like, and surface analysis may be performed by time-of-flight secondary ion mass spectrometry (TOF-SIMS) or the like in the same chamber used for the focused ion beam or the like.

In the land conductor 3a, a plurality of recessed portions 32 (not illustrated in FIG. 2) may be located in a region (first region 3b11) in contact with the via-hole electrical conductor 3b. The oxidized nichrome layer 3b1 may be located in at least one of the recessed portions 32. When the oxidized nichrome layer 3b1 is located in the recessed portion 32, an anchor effect is exhibited, resulting in further improvement in adhesion.

The thickness of the oxidized nichrome layer 3b1 may be 1 nm or more and 100 nm or less as described above and may be smaller than a depth of the recessed portion 32. When the thickness of the oxidized nichrome layer 3b1 is smaller than the depth of the recessed portion 32, the oxidized nichrome layer 3b1 conforms to the recessed portion 32. Therefore, the upper surface of the oxidized nichrome layer 3b1 becomes a curved surface. As a result, the stress relieving effect is further exhibited. The thickness of the oxidized nichrome layer 3b1 and the depth of the recessed portion 32 can be measured by, for example, confirming images of a scanning electron microscope (SEM), a transmission electron microscope (TEM), or the like.

The oxidized nichrome layer 3b1 may be located from a surface in contact with the via-hole electrical conductor 3b to an inside of the recessed portion 32. With such a configuration, in the wiring board 1 according to one embodiment, the oxidized nichrome layer 3a is located even at a boundary between the surface of the land conductor 3b1 and the recessed portion 32 where stress is likely to be concentrated. Therefore, the stress is likely to be relieved. Further, as illustrated in FIG. 2, the oxidized nichrome layer may be located in the third region 3b13. With such a configuration, the wiring board 1 according to one embodiment can relieve stress between the third region 3b13 and the second insulation layer 22. As a result, for example, peeling of the via-hole electrical conductor 3b from the second insulation layer 22 is reduced.

As illustrated in FIG. 2, in the wiring board 1 according to one embodiment, the oxidized nichrome layer 3b1 is located in the second region 3b12 and the third region 3b13. However, the oxidized nichrome layer 3b1 need not be located in the second region 3b12 and the third region 3b13. For example, when the oxidized nichrome layer 3b1 is located in the second region 3b12, for example, peeling of the via-hole electrical conductor 3b from the second insulation layer 22 can be reduced due to the stress relieving effect. Further, ion migration from the nichrome layer 3b2 and the plating layer 3b3 to the insulation layer 2 can be reduced.

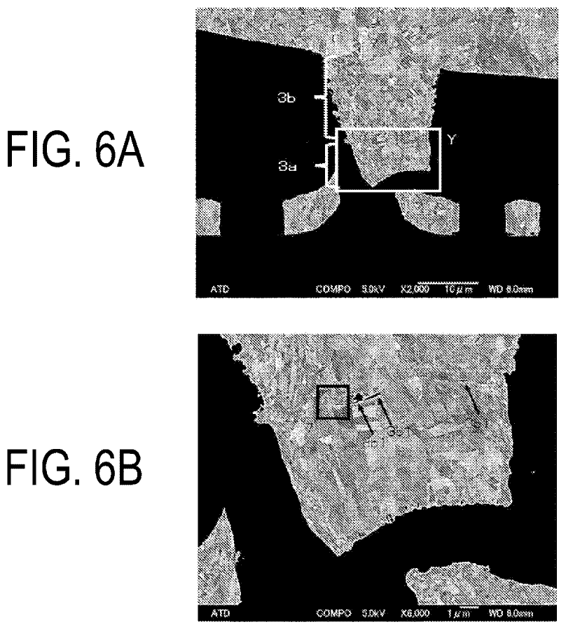

As illustrated in FIG. 6B, the via-hole electrical conductor 3b and the land conductor 3a may have a continuous crystal 7 extending across a boundary between the via-hole electrical conductor 3b and the land conductor 3a. With such a configuration, the connection strength between the via-hole electrical conductor 3b and the land conductor 3a is enhanced. Further, the continuous crystal 7 may be formed via the oxidized nichrome layer 3b1 having a thickness of 1 nm or more and 30 nm or less. With such a configuration, the stress relieving effect can be obtained, and the connection strength is further enhanced. The thickness of the oxidized nichrome layer 3b1 may be 10 nm or more and 20 nm or less. When the oxidized nichrome layer 3b1 has such a thickness, the stress relieving effect can be effectively obtained without inhibiting the formation of the continuous crystal 7. The presence or absence of the continuous crystal 7 and the boundary between the via-hole electrical conductor 3b and the land conductor 3a can be confirmed by, for example, a scanning electron microscope (SEM), a transmission electron microscope (TEM), or the like.

The overall effect on the connection strength between the via-hole electrical conductor 3b and the land conductor 3a can be shown by a via-hole electrical conductor pull test. FIG. 6 are cross-sectional photographs after the via-hole electrical conductor pull test.

The via-hole electrical conductor 3b and the land conductor 3a are illustrated in FIG. 6A. The via-hole electrical conductor 3b and the land conductor 3a being torn while remaining connected to each other in the pull test indicates that the via-hole electrical conductor 3b and the land conductor 3a are firmly connected to each other and a part of the land conductor 3a is torn off in the pull test. FIG. 6B is an enlarged view of region Y surrounded by a square in FIG. 6A. FIG. 6B illustrates that the oxidized nichrome layer 3b1 can be confirmed at an interface between the via-hole electrical conductor 3a and the land conductor 3b1, and the oxidized nichrome layer 3b1 contributes to the stress relief. The oxidized nichrome layer 3b1 can be easily analyzed through Energy Dispersive X-ray Spectroscopy (EDX) or the like.

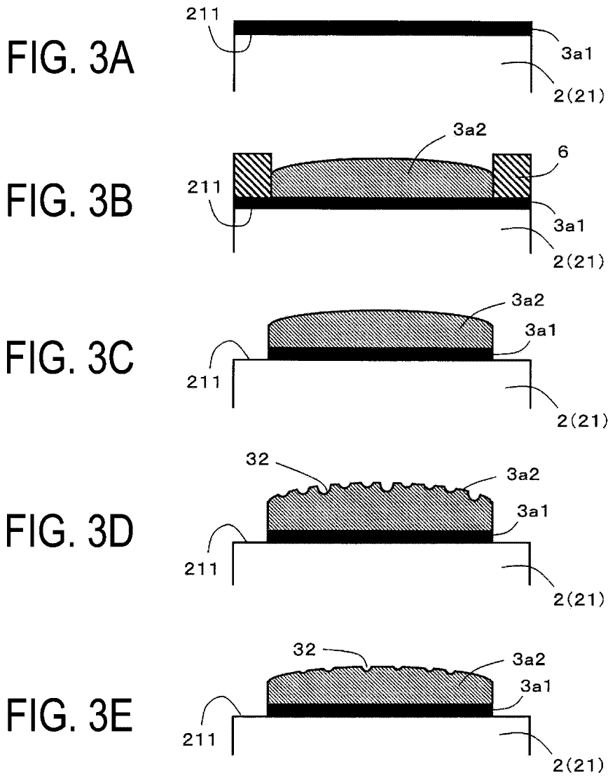

Next, one embodiment of a method of forming the via-hole electrical conductor 3b in the via hole 31 will be described based on FIGS. 3 to 5. FIGS. 3 to 5 illustrate explanatory diagrams for describing an example of the method of forming the via-hole electrical conductor 3b in the wiring board 1 according to one embodiment of the present disclosure.

First, in order to form the land conductor 3a on the first surface 211 of the first insulation layer 21, the first insulation layer 21 in which the seed layer 3a1 is deposited on the first surface 211 is prepared as illustrated in FIG. 3A. Then, as illustrated in FIG. 3B, masking is performed with a resist 6 to form the plating layer 3a2. The seed layer 3a1 and the plating layer 3a2 are as described above, and thus detailed description thereof will be omitted.

Next, as illustrated in FIG. 3C, the resist 6 is peeled off to remove the seed layer 3a1 of the portion masked by the resist 6. A method of removing the seed layer 3a1 may include, for example, etching.

Next, in order to form the recessed portions 32 in the surface of the plating layer 3a2, the plating layer 3a2 is subjected to an annealing treatment, as illustrated in FIG. 3D. The annealing treatment may be performed, for example, at a temperature of 170° C. or higher and 220° C. or lower for 20 minutes or longer and 90 minutes or shorter. By performing the annealing treatment under such conditions, the recessed portions 32 each having an opening diameter of 50 nm or more and 1000 nm or less and a depth of 50 nm or more and 300 nm or less are formed.

After the annealing treatment, as illustrated in FIG. 3E, the surface of the plating layer 3a2 in which the recessed portions 32 are formed is subjected to a soft etching treatment. The soft etching treatment may be performed, for example, for 20 seconds or longer and 60 seconds or shorter using a mixture solution of sulfuric acid and hydrogen peroxide solution. By performing the soft etching treatment, the opening diameter of the recessed portion 32 is set to be 10 nm or more and 500 nm or less, and the depth thereof is set to be 5 nm or more and 50 nm or less. In the wiring board according to the present disclosure, the recessed portions are not necessarily required. Therefore, when not forming the recessed portions, the annealing treatment and the soft etching treatment may be omitted.

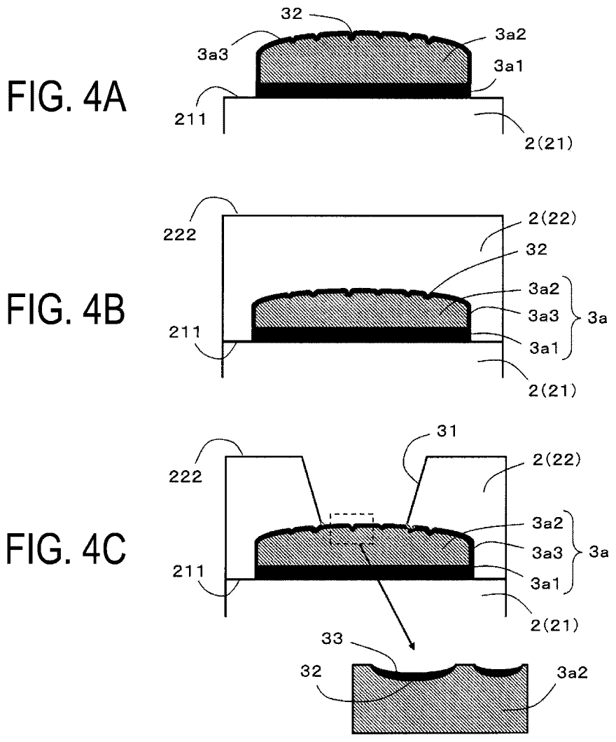

Next, as illustrated in FIG. 4A, the conductors (the seed layer 3a1 and the plating layer 3a2) are subjected to a surface treatment. In the surface treatment, a tin plating process is performed to cover the seed layer 3a1 and the plating layer 3a2, followed by a nitric acid treatment and a silane coupling treatment. Specifically, a tin layer is formed through the tin plating process. A thickness of the tin layer is, for example, 2 nm or more and 5 nm or less. After the tin layer is formed, the tin layer is treated with nitric acid and coated with a silane coupling agent. The silane coupling agent is a compound containing, in the molecule, a functional group that reacts with an inorganic material and a functional group that reacts with an organic material. The silane coupling agent layer has a thickness of, for example, 15 nm or less and may be thicker than the tin layer.

After the surface treatment, as illustrated in FIG. 4B, the second insulation layer 22 is laminated on the first surface 211 of the first insulation layer 21. The second insulation layer 22 is as described above, and thus detailed description thereof will be omitted. As a method of laminating the second insulation layer 22 on the first surface 211, for example, an uncured or semi-cured resin sheet may be placed on the first surface 211 and cured through heating and pressing.

Then, the via hole 31 penetrating from the second surface 222 of the second insulation layer 22 to the land conductor 3a is formed. The method of forming the via hole 31 is not particularly limited, and the via hole 31 is formed using, for example, a laser or the like. The plating layer 3a2 of the land conductor 3a exposed through laser irradiation is cleaned. Cleaning may be performed through, for example, an oxygen plasma treatment, followed by a treatment with a potassium permanganate solution. With this treatment, an oxide film 33 is formed on the entire exposed surface of the plating layer 3a2. Thereafter, in order to remove moisture from the resin (insulation layer 2), the substrate is dried at about 125° C. for about 1 to 2 hours. With this drying, about 80% of moisture is removed.

Next, as illustrated in FIG. 4C, the substrate from which moisture has been removed is subjected to a first sputtering treatment (nitrogen plasma treatment). With the first sputtering treatment, the oxide film 33 on the surface of the plating layer 3a2 is removed, and the oxide film 33 located in the recessed portions remains. The oxide film 33 can be partially removed by changing the output of the plasma.

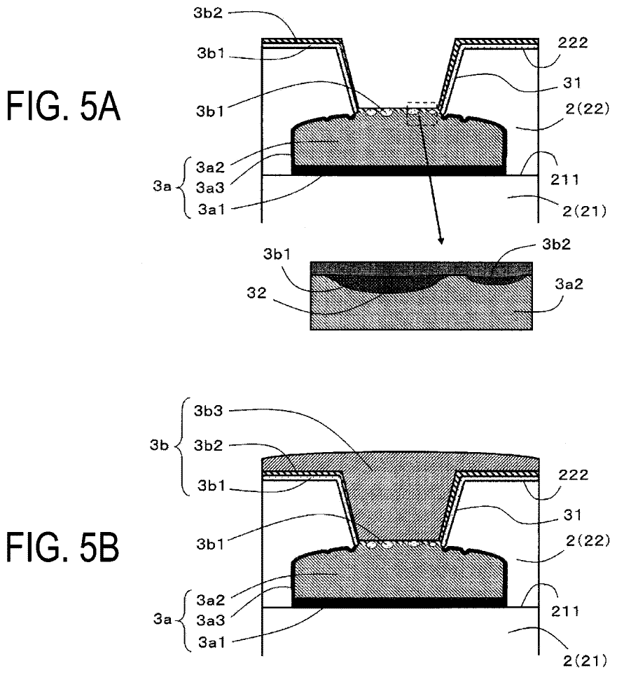

After the first sputtering treatment, the substrate is subjected to a second sputtering treatment (nichrome sputtering treatment) as illustrated in FIG. 5A. With the second sputtering treatment, the nichrome layer 3b2 is formed on the second surface 222 of the second insulation layer 22, a side surface of the via hole 31, and the plating layer 3a2 of the land conductor 3a exposed at the bottom of the via hole 31.

In a portion of the nichrome layer 3b2 that is in contact with the plating layer 3a2 of the land conductor 3a, the nichrome layer 3b2 located in the recessed portions 32 is supplied with oxygen from the oxide film 33 and is changed into the oxidized nichrome layer 3b1. The oxidized nichrome layer 3b1 may be located from the recessed portions 32 to the flat portion. The oxidized nichrome layer 3b1 is located at the boundary portion (corner portion) between the recessed portions 32 and the flat portion where stress is likely to be concentrated, so that the stress relieving effect is further exhibited.

Next, as illustrated in FIG. 5B, the plating layer 3b3 is formed through electrolytic plating. When forming the plating layer 3b3, a resist is usually formed to mask a portion other than the vicinity of the via hole 31. After the plating process, the resist may be removed, and the extra oxidized nichrome layer 3b1 and nichrome layer 3b2 formed on unnecessary portions of the second surface 222 of the second insulation layer 22 may be removed as necessary. Through these steps, the via-hole electrical conductors 3b included in the wiring board 1 according to one embodiment of the present disclosure are formed.

Next, a mounting structure according to the present disclosure will be described. The mounting structure according to one embodiment includes the wiring board 1 according to one embodiment and an element located on a surface of the wiring board 1. The electrical conductor layer 3 in an opening of the solder resist 4 and the electrode of the element are connected via the solder 5. Examples of the element include a semiconductor integrated circuit element and an opto-electronic element. The element may be located on both surfaces of the wiring board 1, or the element may be located on one surface of the wiring board 1 and a motherboard, for example, may be located on the other surface thereof.

The wiring board according to the present disclosure is not limited to the wiring board 1 according to the above-described embodiment. In the wiring board 1 according to one embodiment, the insulation layers 2 constituting the build-up layer have a two-layered structure. However, the insulation layers constituting the build-up layer in the wiring board according to the present disclosure are not limited to the two-layered structure, and may have a laminated structure of three or more layers.

Further, the invention according to the present disclosure is not limited to the above-described embodiments, and various changes or improvements can be made within the scope of the present disclosure described in (1) and (9) below.
(1) A wiring board includes: a first insulation layer having a first surface; a land conductor located on the first surface; a second insulation layer covering the first surface and the land conductor, and has a second surface on a side opposite to the first insulation layer; a via hole penetrating from the second surface of the second insulation layer to the land conductor; and a via-hole electrical conductor located in the via hole and in contact with the land conductor. The via-hole electrical conductor includes a first region in a surface of the via-hole electrical conductor, the first region being in contact with the land conductor. The first region partially includes an oxidized nichrome layer.

With regard to the embodiment of the present disclosure, embodiments illustrated in the (2) to (8) will be further disclosed.
(2) In the wiring board according to the above (1), an area ratio occupied by the oxidized nichrome layer in the first region is 30% or more and 70% or less.
(3) In the wiring board according to the above (1) or (2), the land conductor includes a plurality of recessed portions in a surface in contact with the via-hole electrical conductor, and the oxidized nichrome layer is located in at least one of the plurality of recessed portions.
(4) In the wiring board according to the above (3), a thickness of the oxidized nichrome layer is smaller than a depth of the recessed portion.
(5) In the wiring board according to the above (3) or (4), the oxidized nichrome layer is located from the surface in contact with the via-hole electrical conductor to an inside of the recessed portion.
(6) In the wiring board according to any one of the above (1) to (5), the via-hole electrical conductor includes the oxidized nichrome layer in a second region of the surface of the via-hole electrical conductor, the second region being in contact with an inner wall of the via hole.
(7) In the wiring board according to any one of the above (1) to (6), the via-hole electrical conductor and the land conductor include a continuous crystal extending across a boundary between the via-hole electrical conductor and the land conductor.
(8) In the interconnect substrate according to any one of the above (1) to (7), the oxidized nichrome layer has a thickness of 1 nm or more and 100 nm or less.
(9) A mounting structure includes the wiring board according to any one of the above (1) to (8), and an electronic component located on at least one of an upper surface or a lower surface of the wiring board.

### REFERENCE SIGNS

1 Wiring board
2 Insulation layer
20 Core insulation layer
20a Through-hole conductor
21 First insulation layer
211 First surface
22 Second insulation layer
222 Second surface
3 Electrical conductor layer
31 Via hole
3a Land conductor
3a1 Seed layer
3a2 Plating layer
3a3 Surface treatment layer
3b Via-hole electrical conductor
3b1 Oxidized nichrome layer
3b11 First region
3b12 Second region
3b13 Third region
3b2 Nichrome layer
3b3 Plating layer
32 Recessed portion
33 Oxide film
4 Solder resist
5 Solder
6 Resist
7 Continuous crystal

1. A wiring board comprising:
a first insulation layer having a first surface;
a land conductor located on the first surface;
a second insulation layer covering the first surface and the land conductor, and has a second surface on a side opposite to the first insulation layer;
a via hole penetrating from the second surface of the second insulation layer to the land conductor; and
a via-hole electrical conductor located in the via hole and is in contact with the land conductor,
wherein the via-hole electrical conductor comprises a first region in a surface of the via-hole electrical conductor, the first region being in contact with the land conductor, and
the first region partially comprises an oxidized nichrome layer.

2. The wiring board according to claim 1, wherein an area ratio occupied by the oxidized nichrome layer in the first region is 30% or more and 70% or less.

3. The wiring board according to claim 1, wherein
the land conductor comprises a plurality of recessed portions in a surface in contact with the via-hole electrical conductor, and
the oxidized nichrome layer is located in at least one of the plurality of recessed portions.

4. The wiring board according to claim 3, wherein a thickness of the oxidized nichrome layer is smaller than a depth of the recessed portion.

5. The wiring board according to claim 3, wherein the oxidized nichrome layer is located from the surface in contact with the via-hole electrical conductor to an inside of the recessed portion.

6. The wiring board according to claim 1, wherein the via-hole electrical conductor comprises the oxidized nichrome layer in a second region of the surface of the via-hole electrical conductor, the second region being in contact with an inner wall of the via hole.

7. The wiring board according to claim 1, wherein the via-hole electrical conductor and the land conductor comprise a continuous crystal extending across a boundary between the via-hole electrical conductor and the land conductor.

8. The wiring board according to claim 1, wherein the oxidized nichrome layer has a thickness of 1 nm or more and 100 nm or less.

9. A mounting structure comprising:
the wiring board according to claim 1; and
an electronic component located on at least one of an upper surface or a lower surface of the wiring board.
